(19) United States
(12) Patent Application Publication
(10) Pub. No.: US 2013/0320809 A1
(43) Pub. Date: Dec. 5, 2013

(54) PIEZOELECTRIC VIBRATING PIECE AND PIEZOELECTRIC DEVICE

(71) Applicant: NIHON DEMPA KOGYO CO., LTD., TOKYO (JP)

(72) Inventors: TAKEHIRO TAKAHASHI, SAITAMA (JP); SHUICHI MIZUSAWA, SAITAMA (JP)

(73) Assignee: NIHON DEMPA KOGYO CO., LTD., TOKYO (JP)

(21) Appl. No.: 13/901,567

(22) Filed: May 24, 2013

(30) Foreign Application Priority Data
Jun. 1, 2012 (JP) 2012-125544

(51) Int. Cl. H01L 41/053

(52) U.S. Cl. CPC H01L 41/053
USPC 310/344; 310/348

(57) ABSTRACT

A piezoelectric vibrating piece includes a rectangular vibrator, a framing portion, a connecting portion, and a protrusion. The rectangular vibrator vibrates at a predetermined vibration frequency. The framing portion surrounds a peripheral area of the vibrator. The framing portion includes an inner side surface facing the vibrator. The connecting portion connects the vibrator and the framing portion. The protrusion protrudes to the vibrator side. The protrusion is formed on at least one of the inner side surface facing a side of the vibrator where the connecting portion is connected and the inner side surface adjacent to the connecting portion.

### CROSS REFERENCE TO RELATED APPLICATIONS

This application claims the priority benefit of Japan application serial no. 2012-125544, filed on Jun. 1, 2012. The entirety of the above-mentioned patent application is hereby incorporated by reference herein and made a part of this specification.

### TECHNICAL FIELD

This disclosure relates to a piezoelectric vibrating piece where a framing portion is formed and a piezoelectric device.

### DESCRIPTION OF THE RELATED ART

A piezoelectric vibrating piece that includes a vibrator vibrating at a predetermined vibration frequency, a framing portion surrounding the vibrator, and a connecting portion connecting the vibrator and the framing portion is known. A piezoelectric device where a base plate and a lid plate are to be bonded respectively on one principal surface and the other principal surface of a framing portion of a piezoelectric vibrating piece is also known. This piezoelectric device is employed by being mounted to a printed circuit board or similar member. However, there is a problem that transmission of stress from the printed circuit board to the vibrator varies a characteristic of a vibration frequency of the vibrator.

To solve this problem, for example, Japanese Unexamined Patent Application Publication No. 2007-214942 (hereinafter referred to as Patent Literature 1) discloses that formation of a cutout portion at a connecting portion reduces stress transmitted from the framing portion to the vibrator.

However, with Patent Literature 1, formation of the cutout portion at the connecting portion reduces the strength of the connecting portion, thus there is a concern of a reduction in an impact resistance of the piezoelectric device. Additionally, the connecting portion has a trade-off relationship as follows. If the connecting portion is thinned, the impact resistance of the piezoelectric device lowers while if the connecting portion is thickened, stress is easily transmitted to the vibrator, thus the vibration characteristic easily changes. Therefore, a stress preventing countermeasure that does not rely on the design of the connecting portion only is requested.

A need thus exists for a piezoelectric vibrating piece and a piezoelectric device which are not susceptible to the drawbacks mentioned above.

### SUMMARY

A piezoelectric vibrating piece according to a first aspect includes a rectangular vibrator, a framing portion, a connecting portion, and a protrusion. The rectangular vibrator vibrates at a predetermined vibration frequency. The framing portion surrounds a peripheral area of the vibrator. The framing portion includes an inner side surface facing the vibrator. The connecting portion connects the vibrator and the framing portion. The protrusion protrudes to the vibrator side. The protrusion is formed on at least one of the inner side surface facing a side of the vibrator where the connecting portion is connected and the inner side surface adjacent to the connecting portion.

### BRIEF DESCRIPTION OF THE DRAWINGS

The foregoing and additional features and characteristics of this disclosure will become more apparent from the following detailed description considered with reference to the accompanying drawings, wherein:

FIG. 1 is an exploded perspective view of a piezoelectric device 100;

FIG. 2 is a cross-sectional view taken along the line A-A of FIG. 1;

FIG. 3(a) is a plan view of a piezoelectric vibrating piece 130 on a surface at the +Y′-axis side;

FIG. 3(b) is a plan view of the piezoelectric vibrating piece 130 where an electrode formed on a surface at the −Y′-axis side is illustrated;

FIG. 4(a) is a plan view of a piezoelectric vibrating piece 230 on a surface at the +Y′-axis side;

FIG. 4(b) is a plan view of the piezoelectric vibrating piece 230 where an electrode formed on a surface at the −Y′-axis side is illustrated;

FIG. 5(a) is a plan view of a piezoelectric vibrating piece 330 at the +Y′-axis side;

FIG. 5(b) is a plan view of a piezoelectric vibrating piece 430 at the +Y′-axis side;

FIG. 6(a) is a plan view of a piezoelectric vibrating piece 530 on a surface at the +Y′-axis side;

FIG. 6(b) is a plan view of a piezoelectric vibrating piece 630 on a surface at the +Y′-axis side;

FIG. 7(a) is a plan view of a piezoelectric vibrating piece 730 on a surface at the +Y′-axis side; and

FIG. 7(b) is a plan view of the piezoelectric vibrating piece 730 where an electrode formed on a surface at the −Y′-axis side is illustrated.

### DETAILED DESCRIPTION

The preferred embodiments of this disclosure will be described with reference to the attached drawings. It will be understood that the scope of the disclosure is not limited to the described embodiments, unless otherwise stated.

### Constitution of a Piezoelectric Device 100 According to a First Embodiment

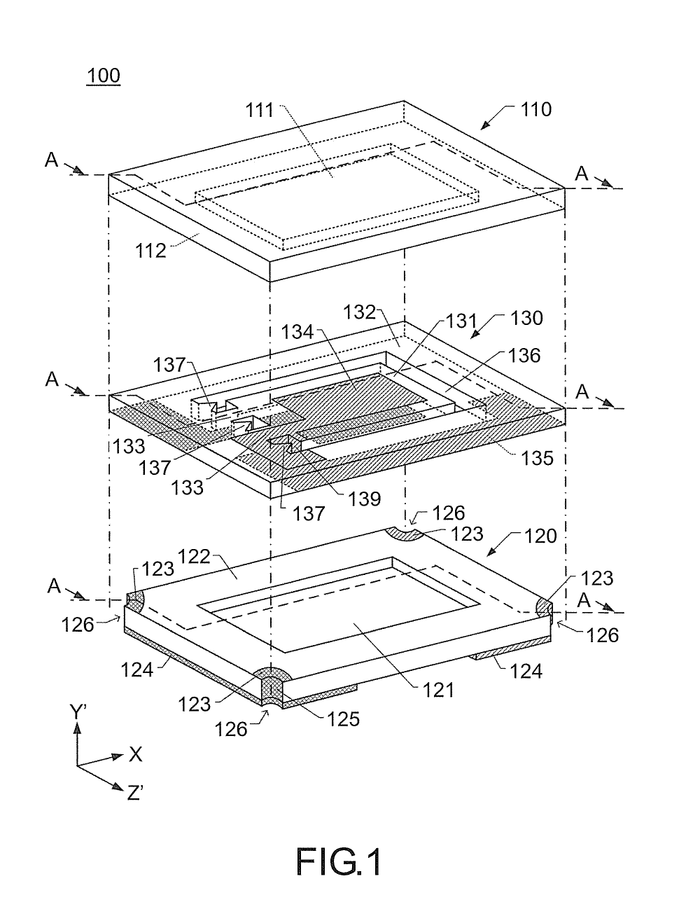

FIG. 1 is an exploded perspective view of the piezoelectric device 100. The piezoelectric device 100 includes a lid plate 110, a base plate 120, and a piezoelectric vibrating piece 130. An AT-cut quartz-crystal vibrating piece, for example, is employed for the piezoelectric vibrating piece 130. The AT-cut quartz-crystal vibrating piece has a principal surface (in the Y-Z plane) that is tilted by 35° 15′ about the Y-axis of crystallographic axes (XYZ) in the direction from the Z-axis to the Y-axis around the X-axis. In the following description, the new axes tilted with reference to the axis directions of the AT-cut quartz-crystal vibrating piece are denoted as the Y′-axis and the Z′-axis. This disclosure defines the long side direction of the piezoelectric device 100 as the X-axis direction, the height direction of the piezoelectric device 100 as the Y′-axis direction, and the direction perpendicular to the X and Y′-axis directions as the Z′-axis direction.

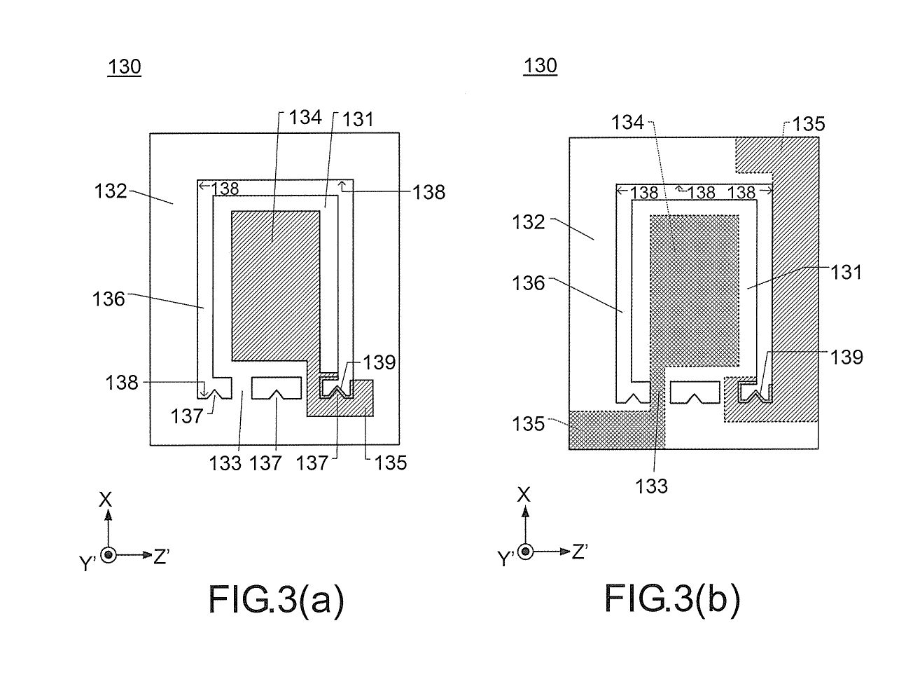

The piezoelectric vibrating piece 130 includes a vibrator 131, a framing portion 132, and two connecting portions 133. The vibrator 131 vibrates at a predetermined vibration frequency and has a rectangular shape. The framing portion 132 surrounds the vibrator 131. The connecting portions 133 connect the vibrator 131 and the framing portion 132. In a region other than the connecting portion 133 between the vibrator 131 and the framing portion 132, a through groove 136 that passes through the piezoelectric vibrating piece 130 in the Y′-axis direction is formed. Excitation electrodes 134 are formed on surfaces at the +Y′-axis side and at the −Y′-axis side of the vibrator 131. An extraction electrode 135 is extracted from each excitation electrode 134 to the framing portion 132 through the connecting portion 133. Additionally, a protrusion 137 is formed on an inner side surface 138 (see FIG. 3(a)) facing the vibrator 131 of the framing portion 132. The protrusion 137 protrudes at the vibrator 131 side.

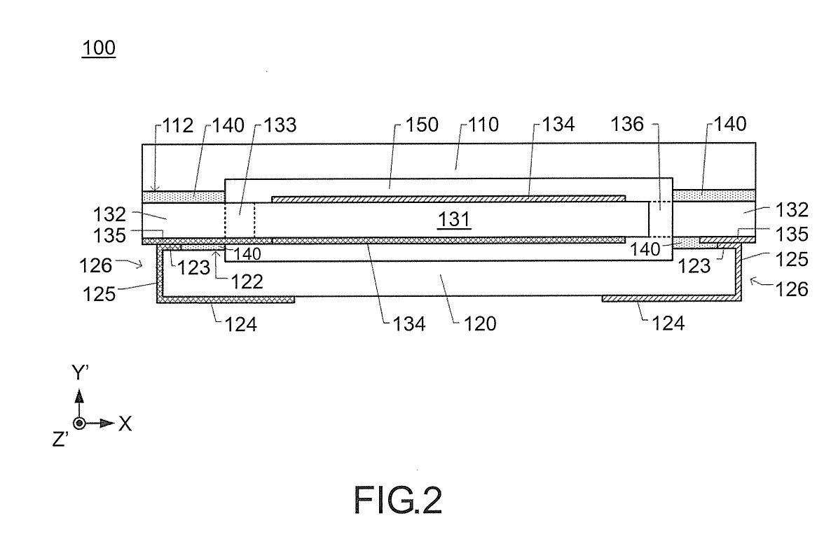

The base plate 120 includes a depressed portion 121, a bonding surface 122, and connecting electrodes 123 on the surface at the +Y′-axis side. The bonding surface 122 surrounds the depressed portion 121. The connecting electrodes 123 are disposed at four corners on the surface at the +Y′-axis side. The bonding surface 122 is to be bonded on the surface at the −Y′-axis side of the framing portion 132 of the piezoelectric vibrating piece 130 via a bonding material 140 (see FIG. 2). Additionally, a pair of mounting terminals 124 is formed on the surface at the −Y′-axis side of the base plate 120. Furthermore, castellations 126 are formed at four corners of side surfaces of the base plate 120. A castellation electrode 125 is formed at the castellation 126. The castellation electrode 125 electrically connects the connecting electrode 123 and the mounting terminal 124. The connecting electrode 123 formed on the corner at the −X-axis side and at the −Z′-axis side electrically connects to the extraction electrode 135 formed on the corner at the −X-axis side and at the −Z′-axis side of the piezoelectric vibrating piece 130. The connecting electrode 123 formed on the corner at the +X-axis side and at the +Z′-axis side electrically connects to the extraction electrode 135 formed on the corner at the +X-axis side and at the +Z′-axis side of the piezoelectric vibrating piece 130.

The lid plate 110 includes a depressed portion 111 and a bonding surface 112 on the surface at the −Y′-axis side. The bonding surface 112 surrounds the depressed portion 111. The bonding surface 112 is to be bonded on the surface at the +Y′-axis side of the framing portion 132 of the piezoelectric vibrating piece 130 via the bonding material 140 (see FIG. 2).

FIG. 2 is a cross-sectional view taken along the line A-A of FIG. 1. The piezoelectric device 100 includes the lid plate 110 at the +Y′-axis side and the base plate 120 at the −Y′-axis side of the piezoelectric vibrating piece 130. Additionally, the piezoelectric device 100 includes a cavity 150 formed by the depressed portion 111 of the lid plate 110 and the depressed portion 121 of the base plate 120. The vibrator 131 is disposed in the cavity 150. The cavity 150 is sealed by forming the bonding materials 140 between the bonding surface 112 of the lid plate 110 and the surface at the +Y′-axis side of the framing portion 132, and between the bonding surface 122 of the base plate 120 and the surface at the −Y′-axis side of the framing portion 132. When the extraction electrode 135 formed at the framing portion 132 electrically connects to the connecting electrode 123 formed at the base plate 120, the excitation electrode 134 electrically connects to the mounting terminal 124.

FIG. 3(a) is a plan view of the piezoelectric vibrating piece 130 on the surface at the +Y′-axis side. The piezoelectric vibrating piece 130 includes a rectangular vibrator 131, the framing portion 132, and two connecting portions 133. The framing portion 132 surrounds the vibrator 131. The connecting portions 133 connect the vibrator 131 and the framing portion 132. The vibrator 131 has short sides at the +X-axis side and at the −X-axis side, and long sides at the +Z′-axis side and at the −Z′-axis side. Assume that a side surface facing the vibrator 131 of the framing portion 132 is the inner side surface 138. The two connecting portions 133 connect to the inner side surface 138 at the −X-axis side of the vibrator 131. Additionally, the triangular protrusion 137 is formed at the inner side surface 138 at the −X-axis side of the vibrator 131. The protrusion 137 protrudes from the inner side surface 138 in a direction of the vibrator 131. The protrusions 137 are respectively formed at the −Z′-axis side of the connecting portion 133 at the −Z′-axis side, at the +Z′-axis side of the connecting portion 133 at the +Z′-axis side, and between the two connecting portions 133. Moreover, the extraction electrode 135 extracted from the excitation electrode 134 formed on the surface at the +Y′-axis side of the vibrator 131 is connected to a side surface electrode 139 formed at a side surface at the end of the +Z′-axis side at the −X-axis side of the through groove 136 through the connecting portion 133 at the +Z′-axis side.

FIG. 3(b) is a plan view of the piezoelectric vibrating piece 130 where an electrode formed on a surface at the −Y′-axis side is illustrated. FIG. 3(b) illustrates a view where the surface at the −Y′-axis side of the piezoelectric vibrating piece 130 is transparently viewed from the +Y′-axis side in the −Y′-axis direction. The extraction electrode 135 is extracted from the excitation electrode 134 formed on the surface at the −Y′-axis side of the vibrator 131 to a corner at the −Z′-axis side on a side at the −X-axis side on the surface at the −Y′-axis side of the framing portion 132 through the connecting portion 133 at the −Z′-axis side. Additionally, the extraction electrode 135 is extracted from the side surface electrode 139 formed at the through groove 136 to a corner at the +Z′-axis side at the +X-axis side on the surface at the −Y′-axis side of the framing portion 132 through the framing portion 132 at the +Z′-axis side.

When the piezoelectric device 100 is mounted to a printed circuit board or similar member, stress is applied from the printed circuit board to the piezoelectric device 100. This stress is transmitted to the vibrator 131 and causes a change in a characteristic of a vibration frequency of the vibrator 131. Especially, if the stress is generated by bending the printed circuit board, and this bending stress is applied to the short side of the framing portion 132 where the connecting portion 133 is connected, this bending stress is easily transmitted to the vibrator 131 and considerably affects the characteristic of the vibration frequency. If a width of the connecting portion 133 is narrow, it is difficult to transmit the stress of the framing portion 132 to the vibrator 131; therefore, the vibrator 131 is less affected. However, if an impact resistance of the connecting portion 133 is reduced, the piezoelectric device 100 tends to be damaged by an impact such as a drop of the piezoelectric device 100. On the other hand, if the connecting portion 133 is formed with a large width, the impact resistance of the piezoelectric device 100 increases. However, stress generated at the framing portion 132 is easily transmitted to the vibrator 131; therefore, the stress tends to affect a vibration of the vibrator 131. In contrast to this, in the piezoelectric device 100, formation of the protrusion 137 reduces stress applied to the connecting portion 133. Accordingly, impact resistance of the piezoelectric device 100 increases; therefore, stress transmitted to the vibrator 131 is reduced, which reduces a change in the characteristic of the vibration frequency.

In the piezoelectric device 100, since the protrusion 137 is formed at the inner side surface 138 of the framing portion 132 where the connecting portion 133 is connected, a cross-sectional area of the framing portion 132 changes. The amount of stress transmitted to the framing portion 132 also changes in the framing portion 132. This change in stress concentrates on a portion where the cross-sectional area of the framing portion 132 substantially changes, such as a portion where the protrusion 137 is disposed. That is, stress generated in the framing portion 132 is dispersed to the protrusion 137, and stress of the framing portion 132 is not concentrated only at the connecting portion 133. Consequently, stress applied to the connecting portion 133 is reduced. Since reduction in stress applied to the connecting portion 133 also reduces stress transmitted to the vibrator 131, stress from the framing portion 132 less affects the vibrator 131, thus inhibiting vibration to the vibrator 131 from being affected. That is, in the piezoelectric device 100, reduction in an influence of stress to the vibrator 131 allows room for increasing the width of the connecting portion 133. A satisfactory impact resistance can be achieved by widening the connecting portion 133.

Additionally, with the piezoelectric vibrating piece 130, the width of the framing portion 132 is not cut to be thin. This is preferred since strength of the framing portion 132 is not reduced. Furthermore, since an area where the bonding material 140 is formed does not become narrow, sealing strength of the cavity 150 is not reduced.

While in the piezoelectric vibrating piece 130 illustrated in FIG. 3(a) and FIG. 3(b), the connecting portions 133 are connected adjacent to both ends on a side at the −X-axis side of the vibrator 131, the connecting portions 133 may be connected to both ends on the side at the −X-axis side of the vibrator 131. The three protrusions 137 are formed at the piezoelectric vibrating piece 130. However, even only a single protrusion 137 can reduce stress applied to the connecting portion 133.

### Second Embodiment

A piezoelectric vibrating piece may be different from the piezoelectric vibrating piece 130 in a position where the connecting portion is connected, the number of connecting portions, or similar specification. Additionally, a protrusion shape of the protrusion 137 may be different. A description will be given of a piezoelectric vibrating piece 230 to a piezoelectric vibrating piece 730 as a modification of a piezoelectric vibrating piece. Like reference numerals designate corresponding or identical elements throughout the first embodiment and the second embodiment, and therefore such elements will not be further elaborated here.

### Constitution of the Piezoelectric Vibrating Piece 230

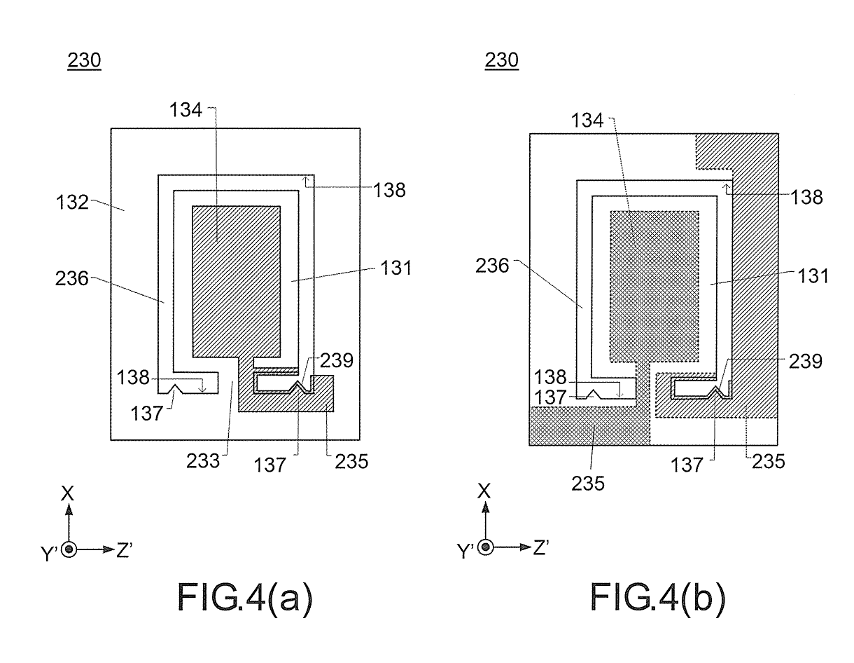

FIG. 4(a) is a plan view of the piezoelectric vibrating piece 230 on the surface at the +Y′-axis side. The piezoelectric vibrating piece 230 includes the vibrator 131, the framing portion 132, and one connecting portion 233. In the piezoelectric vibrating piece 230, the connecting portion 233 connects to the center of the side at the −X-axis side of the vibrator 131. A through groove 236 is formed between the vibrator 131 and the framing portion 132. Further, in the piezoelectric vibrating piece 230, the protrusions 137 at the inner side surface 138 at the −X-axis side of the vibrator 131 are formed at the +Z′-axis side and at the −Z′-axis side of the connecting portion 233. An extraction electrode 235 is extracted from the excitation electrode 134 formed at the +Y′-axis side of the vibrator 131 to the −X-axis side and the +Z′-axis side of the through groove 236. The extraction electrode 235 electrically connects to a side surface electrode 239 formed on the side surface at the −X-axis side and at the +Z′-axis side of the through groove 236.

FIG. 4(b) is a plan view of the piezoelectric vibrating piece 230 where an electrode formed on a surface at the −Y′-axis side is illustrated. FIG. 4(b) illustrates a view where the surface at the −Y′-axis side of the piezoelectric vibrating piece 230 is viewed transparently from the +Y′-axis side in the −Y′-axis direction. The extraction electrode 235 is extracted from the excitation electrode 134 formed on the surface at the −Y′-axis side of the vibrator 131 to a corner at the −Z′-axis side on a side at the −X-axis side on the surface at the −Y′-axis side of the framing portion 132 through the surface at the −Y′-axis side of the connecting portion 233. Additionally, the extraction electrode 235 is extracted from the side surface electrode 239 formed at the through groove 236 to a corner at the +X-axis side and at the +Z′-axis side on the surface at the −Y′-axis side of the framing portion 132 through the framing portion 132 at the +Z′-axis side.

With the piezoelectric vibrating piece 230, similarly to the piezoelectric vibrating piece 130, focusing the stress on the protrusion 137 formed at the framing portion 132 disperses stress generated at the framing portion 132, thus reducing stress applied to the connecting portion 233. This improves an impact resistance of the piezoelectric vibrating piece 230, thus reducing a variation of a vibration frequency.

### Constitution of a Piezoelectric Vibrating Piece 330

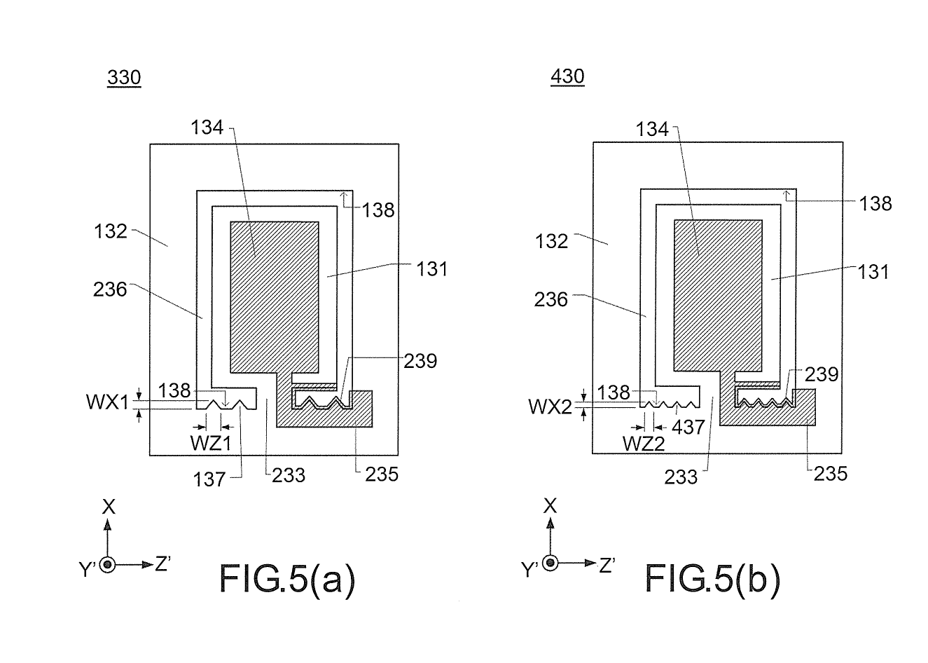

FIG. 5(a) is a plan view of the piezoelectric vibrating piece 330 at the +Y′-axis side. The piezoelectric vibrating piece 330 includes the vibrator 131, the framing portion 132, and the connecting portion 233. Additionally, the two protrusions 137 are formed at each of the +Z′-axis side and −Z′-axis side of the connecting portion 233 (four in total). As illustrated in the piezoelectric vibrating piece 330 in FIG. 5(a), two or more protrusions 137 may be formed at the inner side surface 138. An increase in the number of formed protrusions 137 facilitates dispersion of stress applied to the framing portion 132, also reducing stress applied to the connecting portion 233.

### Constitution of a Piezoelectric Vibrating Piece 430

FIG. 5(b) is a plan view of the piezoelectric vibrating piece 430 at the +Y′-axis side. The piezoelectric vibrating piece 430 includes the vibrator 131, the framing portion 132, and the connecting portion 233. Four protrusions 437 are formed at each of the +Z′-axis side and the −Z′-axis side of the connecting portion 233. The protrusion 437 has a triangular shape in a plane surface. Assume that a width in the X-axis direction of the protrusion 137 is a width WX1 and a width in the Z′-axis direction of the protrusion 137 is a width WZ1 (see FIG. 5(a)). The protrusion 437 has a width WX2, which is smaller than the width WX1 in the X-axis direction, and a width WZ2, which is smaller than the width WZ1 in the Z′-axis direction. The piezoelectric vibrating piece may include a large number of small protrusions as illustrated in FIG. 5(b) or, conversely, may include a large protrusion.

### Constitution of a Piezoelectric Vibrating Piece 530

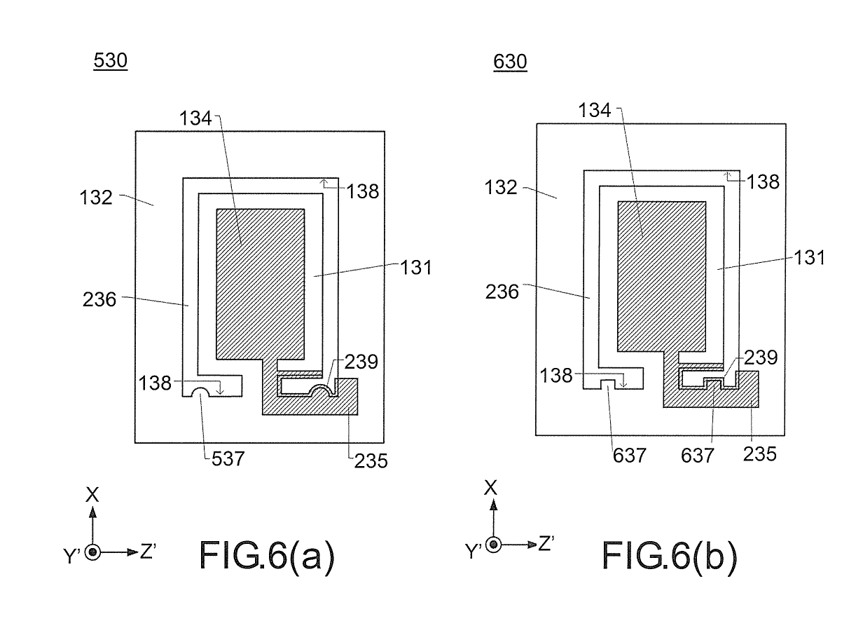

FIG. 6(a) is a plan view of the piezoelectric vibrating piece 530 on the surface at the +Y′-axis side. The piezoelectric vibrating piece 530 includes the vibrator 131, the framing portion 132, and the connecting portion 233. One protrusion 537 is formed at each of the +Z′-axis side and −Z′-axis side of the connecting portion 233. The protrusion 537 has a semicircle shape in a plane surface. The protruded plane surface may be formed into a semicircle shape where the distal end is not pointed like the protrusion 137.

### Constitution of a Piezoelectric Vibrating Piece 630

FIG. 6(b) is a plan view of the piezoelectric vibrating piece 630 on the surface at the +Y′-axis side. The piezoelectric vibrating piece 630 includes the vibrator 131, the framing portion 132, and the connecting portion 233. One protrusion 637 is formed at each of the +Z′-axis side and −Z′-axis side of the connecting portion 233. The protrusion 637 has an angular shape in a plane surface. The planar surface of the protrusion may be formed into an angular shape like the protrusion 637.

### Constitution of the Piezoelectric Vibrating Piece 730

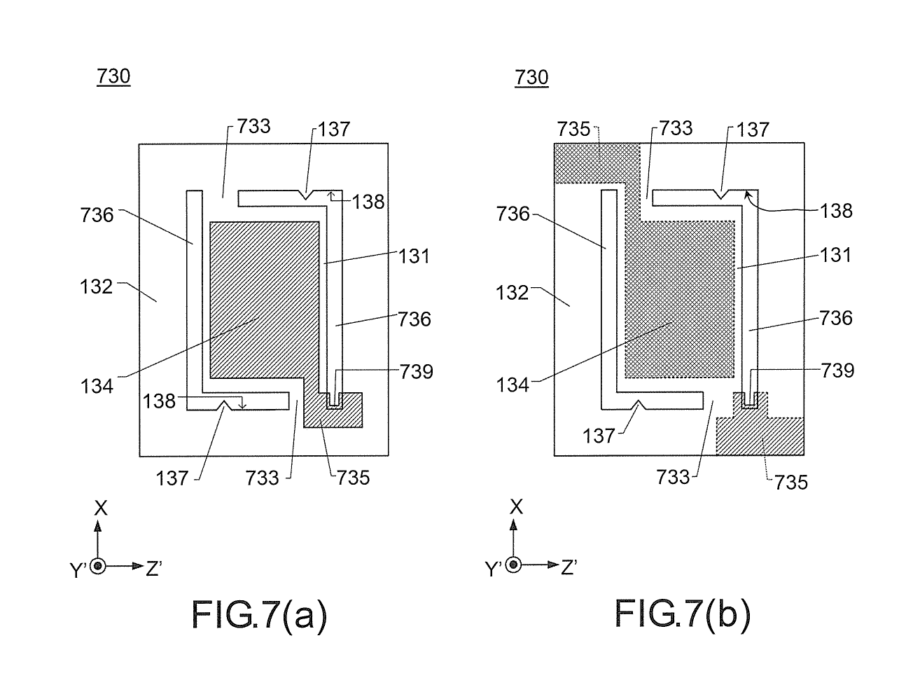

FIG. 7(a) is a plan view of the piezoelectric vibrating piece 730 on the surface at the +Y′-axis side. The piezoelectric vibrating piece 730 includes the vibrator 131, the framing portion 132, and a connecting portion 733. The connecting portion 733 connects to each of the +X-axis side and −Z′-axis side and −X-axis side and +Z′-axis side of the vibrator 131. A through groove 736 is formed between the vibrator 131 and the framing portion 132. Additionally, in the piezoelectric vibrating piece 730, one protrusion 137 is formed at each of the inner side surfaces 138 at the +X-axis side and −X-axis side of the vibrator 131. Additionally, an extraction electrode 735 is extracted from the excitation electrode 134 formed at the +Y′-axis side of the vibrator 131 to the −X-axis side and the +Z′-axis side of the through groove 736 via the connecting portion 733 connected at the −X-axis side of the vibrator 131. The extraction electrode 735 electrically connects to a side surface electrode 739 formed on the side surface at the −X-axis side and the +Z′-axis side of the through groove 736.

FIG. 7(b) is a plan view of the piezoelectric vibrating piece 730 where an electrode formed on the surface at the −Y′-axis side is illustrated. FIG. 7(b) illustrates a view where the surface at the −Y′-axis side of the piezoelectric vibrating piece 730 is viewed transparently from the +Y′-axis side in the −Y′-axis direction. The extraction electrode 735 is extracted from the excitation electrode 134 formed on the surface at the −Y′-axis side of the vibrator 131 to a corner at the −Z′-axis side on a side at the +X-axis side on the surface at the −Y′-axis side of the framing portion 132 through the surface at the −Y′-axis side of the connecting portion 733 formed at the +X-axis side. Additionally, the extraction electrode 735 is extracted from the side surface electrode 739 formed at the through groove 736 to a corner at the −X-axis side and at the +Z′-axis side on the surface at the −Y′-axis side of the framing portion 132.

In the piezoelectric vibrating piece 730, the protrusions 137 are formed at the inner side surface 138 at each of the +X-axis side and −X-axis side of the framing portion 132 where the connecting portion 733 is connected. Therefore, in the respective parts at the +X-axis side and the −X-axis side of the framing portion 132, stress of the framing portion 132 is dispersed, thus reducing concentration of stress to each connecting portion 733. This reduces stress applied to the connecting portion 733 and improves an impact resistance of the piezoelectric vibrating piece 730, thus reducing a variation of a vibration frequency.

Representative embodiments are described in detail above; however, as will be evident to those skilled in the relevant art, this disclosure may be changed or modified in various ways within its technical scope.

For example, the protrusion may not be formed at the inner side surface at the same side as the inner side surface where the connecting portion is connected. For example, in FIG. 7(a), the protrusion 137 may be formed adjacent to each connecting portion 733, that is, at the +X-axis side of the inner side surface 138 of the framing portion 132 at the −Z′-axis side, and at the −X-axis side of the inner side surface 138 of the framing portion 132 at the +Z′-axis side. Formation of the protrusion 137 adjacent to the connecting portion 733 can reduce stress applied to the peripheral area of the connecting portion 733. This consequently reduces stress applied to the connecting portion 733.

Additionally, the above-described embodiments disclose a case where the piezoelectric vibrating piece is an AT-cut quartz-crystal vibrating piece. A BT-cut quartz-crystal vibrating piece or similar member that similarly vibrates in the thickness-shear mode is similarly applicable. Further, the piezoelectric vibrating piece is basically applicable to a piezoelectric material that includes not only a quartz-crystal material but also lithium tantalate, lithium niobate, and piezoelectric ceramics.

In the first aspect of the disclosure, the piezoelectric vibrating piece according to a second aspect is configured as follows. The connecting portion connects to the inner side surface that faces a short side of the vibrator.

In the first aspect and the second aspect of the disclosure, the piezoelectric vibrating piece according to a third aspect is configured as follows. A number of the connecting portions is one.

In the first aspect and the second aspect of the disclosure, the piezoelectric vibrating piece according to a fourth aspect is configured as follows. A number of the connecting portions is two. The respective connecting portions connect to both ends of one short side of the vibrator or adjacent to both ends.

In the first aspect and the second of the disclosure, the piezoelectric vibrating piece according to a fifth aspect is configured as follows. A number of the connecting portions is two, and each of the connecting portions connects to one short side and another short side of the vibrator.

In the first aspect to the fifth aspect of the disclosure, the piezoelectric vibrating piece according to a sixth aspect is configured as follows. A plurality of the protrusions is formed at the inner side surface where the connecting portion is connected.

In the first aspect to the sixth aspect of the disclosure, the piezoelectric vibrating piece according to a seventh aspect is configured as follows. The protrusion is formed into a triangular shape, an angular shape, or a semicircle shape.

A piezoelectric device according to an eighth aspect is configured as follows. The piezoelectric device includes a piezoelectric vibrating piece according to the first aspect to the seventh aspect, a base plate to be bonded on one principal surface of the piezoelectric vibrating piece, and a lid plate to be bonded on another principal surface of the piezoelectric vibrating piece to seal the vibrator.

With the piezoelectric vibrating piece and the piezoelectric device according to the embodiments, a variation of a characteristic of a vibration frequency of the vibrator can be reduced by less affecting stress transmitted to the vibrator.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a rectangular vibrator that vibrates at a predetermined vibration frequency;
a framing portion that surrounds a peripheral area of the vibrator, the framing portion including an inner side surface facing the vibrator;
a connecting portion that connects the vibrator and the framing portion; and
a protrusion that protrudes to the vibrator side, the protrusion being formed on at least one of the inner side surface facing a side of the vibrator where the connecting portion is connected and the inner side surface adjacent to the connecting portion.

2. The piezoelectric vibrating piece according to claim 1, wherein
the connecting portion connects to the inner side surface that faces a short side of the vibrator.

3. The piezoelectric vibrating piece according to claim 1, wherein
a number of the connecting portion is one.

4. The piezoelectric vibrating piece according to claim 1, wherein
a number of the connecting portions is two, and
the respective connecting portions connecting to both ends of one short side of the vibrator or adjacent to both ends.

5. The piezoelectric vibrating piece according to claim 1, wherein
a number of the connecting portions is two, and
each of the connecting portions connects to one short side and another short side of the vibrator.

6. The piezoelectric vibrating piece according to claim 1, wherein
a plurality of the protrusions is formed at the inner side surface where the connecting portion is connected.

7. The piezoelectric vibrating piece according to claim 1, wherein
the protrusion is formed into a triangular shape, an angular shape, or a semicircle shape.

8. A piezoelectric device, comprising:
the piezoelectric vibrating piece according to claim 1;
a base plate to be bonded on one principal surface of the piezoelectric vibrating piece; and
a lid plate to be bonded on another principal surface of the piezoelectric vibrating piece to seal the vibrator.
